(19) United States
(12) Patent Application Publication
(10) Pub. No.: US 2013/0229200 A1
(43) Pub. Date: Sep. 5, 2013

(54) TESTING APPARATUS FOR PERFORMING AN AVALANCHE TEST AND METHOD THEREOF

(71) Applicants: CHOON LEONG LOU, HSINCHU CITY (TW); TOAN TONTHAT, HSINCHU CITY (TW)

(72) Inventors: CHOON LEONG LOU, HSINCHU CITY (TW); TOAN TONTHAT, HSINCHU CITY (TW)

(73) Assignee: STAR TECHNOLOGIES, INC., HSINCHU CITY (TW)

(21) Appl. No.: 13/412,298

(22) Filed: Mar. 5, 2012

(51) Int. Cl. G01R 31/26

(52) U.S. Cl. 324/756.01

(57) ABSTRACT

A testing apparatus for performing an avalanche test comprises a wafer chuck configured to retain a wafer having a plurality of transistors, an inductor with a first end connected to a drain terminal of the transistor, a power source configured to provide a current to a second end of the inductor through a switch, a meter connected to a source terminal of the transistor through the wafer chuck, and a driver configured to synchronously control the operation of the switch and the operation of the transistor.

### BACKGROUND OF THE INVENTION

1. Technical Field

The present invention relates to a testing apparatus for performing an avalanche test, and more particularly, to a testing apparatus for performing an avalanche test on transistors at the wafer level and method thereof.

2. Background

Generally, it is necessary to test the electrical characteristics of integrated circuit devices at the wafer level to verify the performance of the integrated circuit device and to confirm whether the device satisfies the product specification. Integrated circuit devices with electrical characteristics satisfying the specification are selected for the subsequent packaging process, while the other devices are discarded to avoid incurring additional packaging cost. Another electrical property test is performed on the integrated circuit device after the packaging process is completed in order to screen out any substandard devices and increase the product yield.

U.S. Pat. No. 7,368,934 discloses an avalanche test circuit for applying an avalanche test signal to an integrated circuit device under test after the packaging process. The avalanche test circuit comprises a series combination of a voltage source and an inductance; a switching device connected in parallel with said series combination; a diode for being connected to a test terminal of said device under test, said diode being connected to a connection point of said inductance and said switching device; and a common terminal of said device under test being connected to a connection point of said switching device and said voltage source.

### SUMMARY

One aspect of the present invention provides a testing apparatus for performing an avalanche test on the integrated circuit devices at the wafer level and method thereof.

In one embodiment of the present invention, a testing apparatus for performing an avalanche test comprises a wafer chuck configured to retain a wafer having a plurality of transistors, an inductor with a first end connected to a drain terminal of the transistor, a power source configured to provide a current to a second end of the inductor through a switch, a meter connected to a source terminal of the transistor through the wafer chuck, and a driver configured to synchronously control the operation of the switch and the operation of the transistor.

In one embodiment of the present invention, a testing method for performing an avalanche test comprises the steps of sinking a current from a wafer chuck retaining a wafer having a plurality of transistors, charging an inductor with a first end connected to a drain terminal of the transistor, synchronously turning on the transistor and stopping the charging of the inductor, and measuring the current flowing through a source terminal of the transistor.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 and FIG. 2 illustrate a testing apparatus for performing the avalanche test of the transistors at the wafer level according to one embodiment of the present invention;

FIG. 3 illustrates a testing method for performing the avalanche test of the transistors at the wafer level according to one embodiment of the present invention;

FIG. 4 illustrates the waveform of the voltage applied on the gate terminal of the transistor and the current waveform of the inductor according to one embodiment of the present invention;

FIG. 5 illustrates the current waveform of the drain terminal of the transistor and the current waveform of the common source terminal of the transistor according to one embodiment of the present invention; and

FIG. 6 illustrates the current waveform of the drain terminal of the transistor and the current waveform of the common source terminal of the transistor according to the prior art.

### DETAILED DESCRIPTION

To avoid incurring additional packaging cost, the avalanche test can be performed at the wafer level, rather than after the packaging process as in the prior art, so as to discard any devices not complying with the avalanche specification before the packaging process. However, one major problem with conducting the avalanche test at the wafer level is that, because the devices formed on the wafer have a common source, the wafer is placed on the chuck during the wafer level testing, and the wafer chuck acts as a large capacitor such that the current passing through the device under test cannot flow to the current meter of the tester.

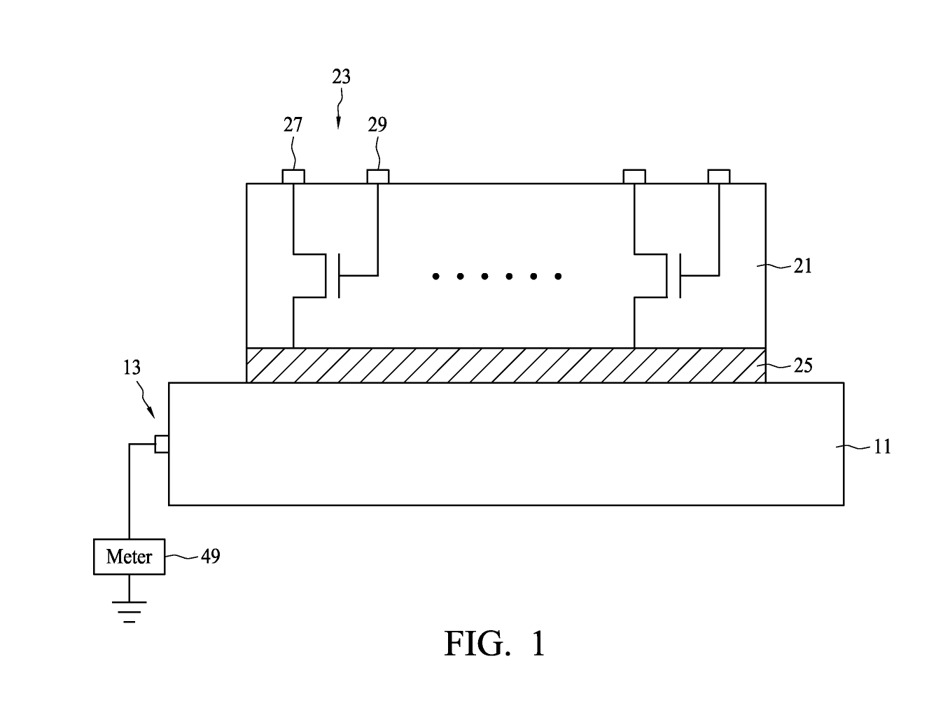

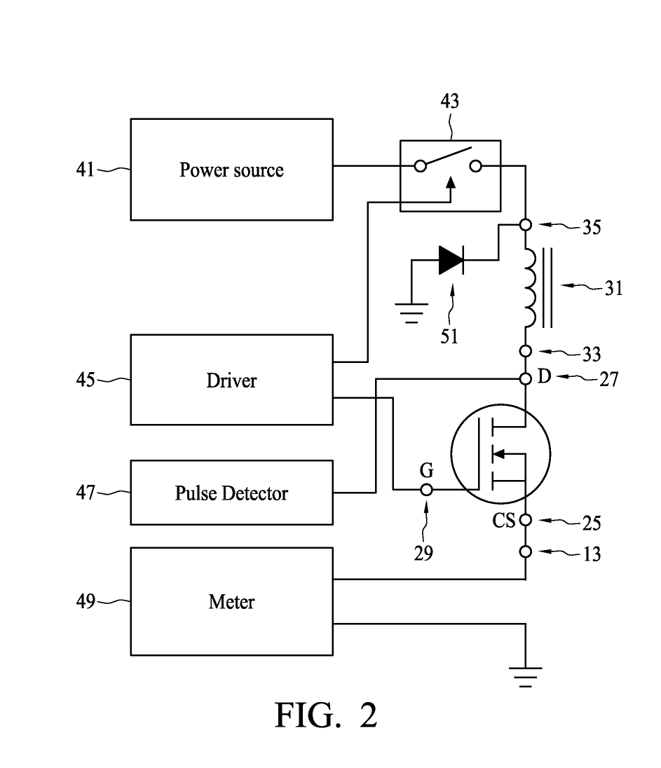

FIG. 1 and FIG. 2 illustrate a testing apparatus 10 for performing the avalanche test of the transistors at the wafer level according to one embodiment of the present invention. In one embodiment of the present invention, the testing apparatus 10 comprises a wafer chuck 11 configured to retain a wafer 21 having a plurality of transistors 23, an inductor 31 with a first end 33 connected to a drain terminal 27 of the transistor 23, a power source 41 such as a high voltage source or high current source configured to provide a current to a second end 35 of the inductor 31 through a switch 43, a meter 49 connected to a source terminal 25 of the transistor 23 through one contact 13 of the wafer chuck 11, and a driver 45 such as a high slew rate voltage drive configured to synchronously control the operation of the switch 43 and the operation of the transistor 23. In one embodiment of the present invention, the testing apparatus 10 further comprises a pulse detector 47 connected to the drain terminal 27 of the transistor 23 and a blocking device 51 such as a blocking diode connected to the second end 35 of the inductor 31.

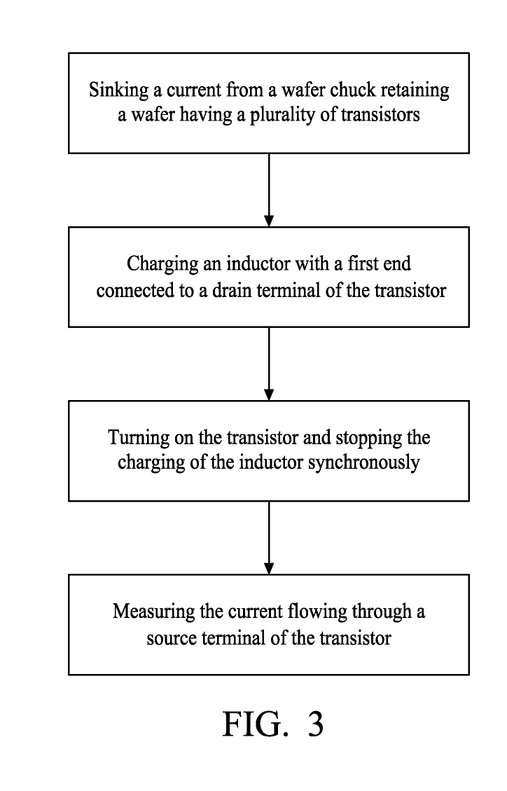

FIG. 3 illustrates a testing method for performing the avalanche test of the transistors at the wafer level according to one embodiment of the present invention. In one embodiment of the present invention, the testing method for performing the avalanche test comprises the steps of sinking a current from a wafer chuck retaining a wafer having a plurality of transistors, charging an inductor with a first end connected to a drain terminal of the transistor, synchronously turning on the transistor and stopping the charging of the inductor, and measuring the current flowing through a source terminal of the transistor. In one embodiment of the present invention, the sinking of a current from a wafer chuck include grounding the wafer chuck, i.e., sinking the current from the common source terminal of the wafer via the wafer chuck.

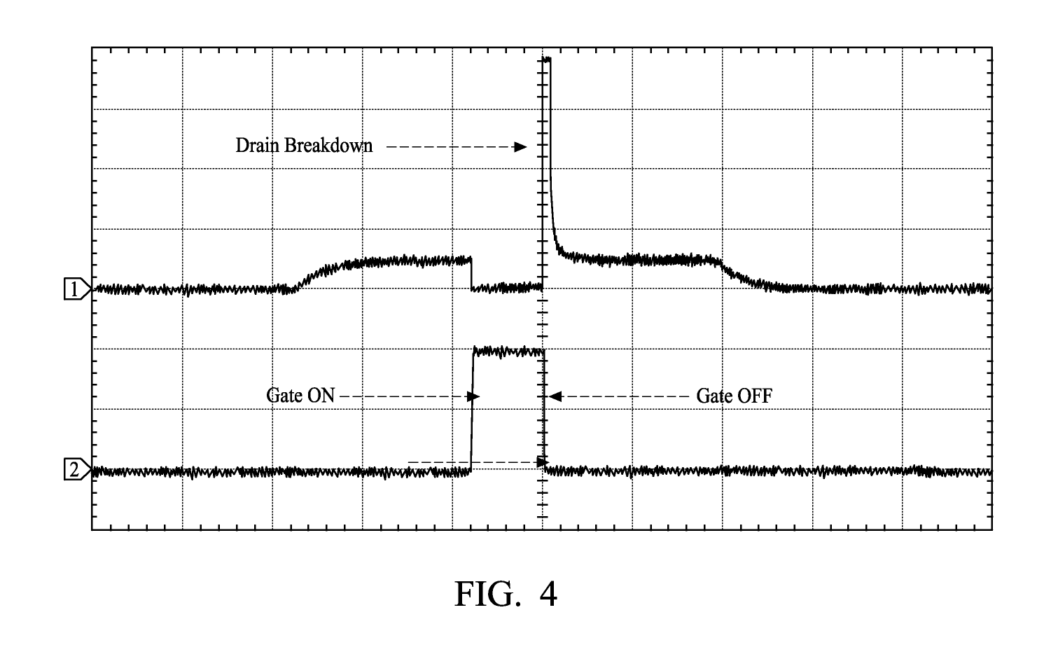

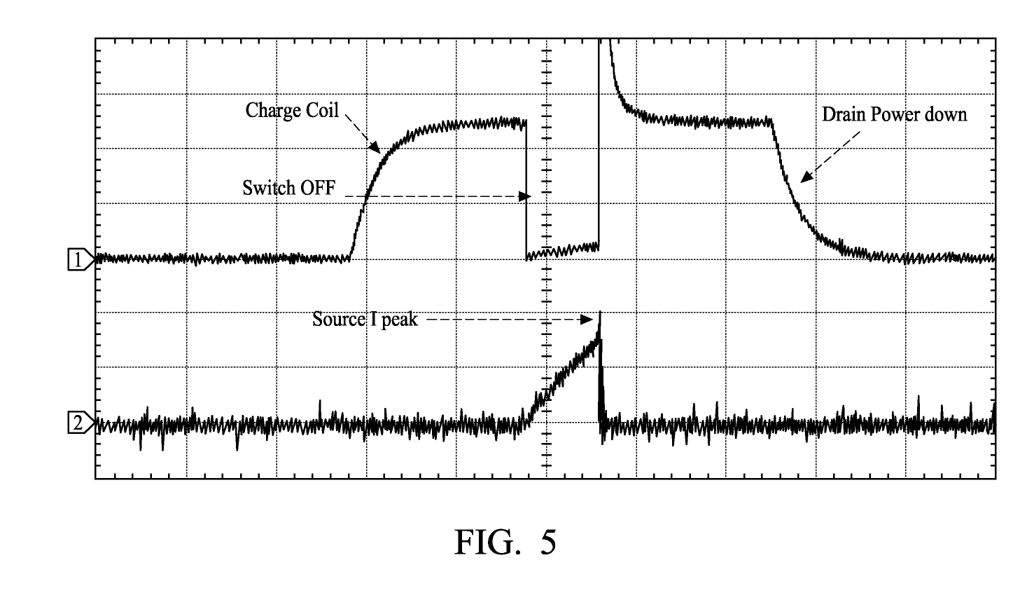

FIG. 4 illustrates the waveform of the voltage applied on the gate terminal of the transistor and the current waveform of the inductor according to one embodiment of the present invention, and FIG. 5 illustrates the current waveform of the drain terminal 27 of the transistor 23 and the current waveform of the source terminal 25 of the transistor 23 according to one embodiment of the present invention. As shown in the drawings, the present testing apparatus and testing method can accurately measure the current peak on the common source terminal 25 of the transistor 23 as the switch 43 is turned off and the transistor 23 is synchronously turned on, even when the avalanche test is performed at the wafer level.

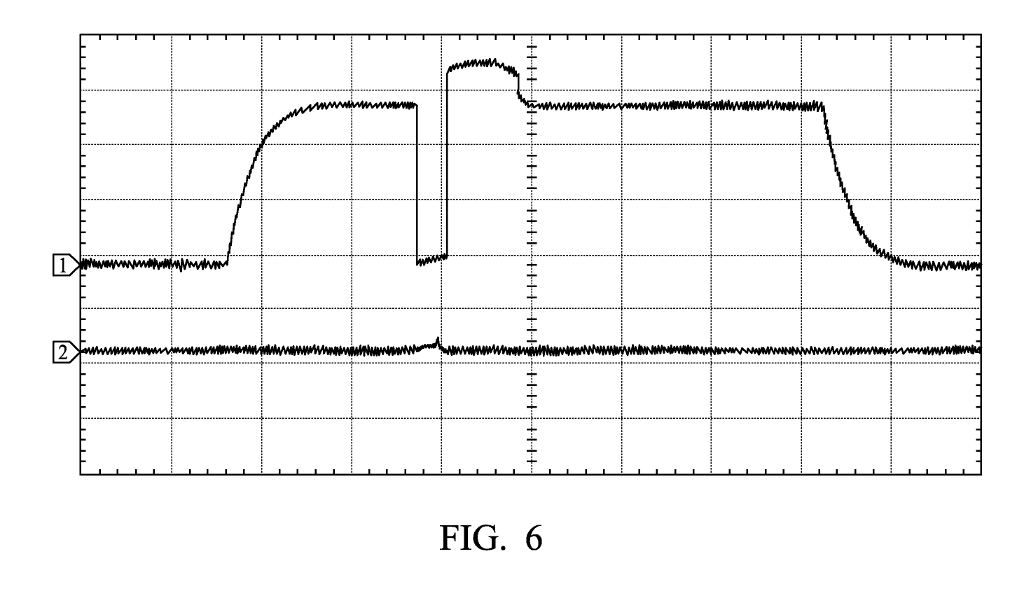

In the prior art, because the wafer chuck 11 acts as a large capacitor, the current passing through the common source terminal 25 of the transistor 23 is distributed to the wafer chuck 11 rather than flowing to the meter 13, and there is no current peak, as shown in FIG. 6. In contrast, in one embodiment of the present invention, by sinking the current from the source terminal 25 via the wafer chuck 11 and by synchronously turning on the transistor 23 and turning off the switch 43, the present testing apparatus and testing method can accurately measure the current peak on the common source terminal 25 of the transistor 23.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A testing apparatus for performing an avalanche test, comprising:
a wafer chuck configured to retain a wafer having a plurality of transistors;
an inductor with a first end connected to a drain terminal of the transistor;
a power source configured to provide a current to a second end of the inductor through a switch;
a meter connected to a source terminal of the transistor through the wafer chuck; and
a driver configured to synchronously control the operation of the switch and the operation of the transistor.

2. The testing apparatus for performing an avalanche test of claim 1, further comprising a pulse detector connected to the drain terminal of the transistor.

3. The testing apparatus for performing an avalanche test of claim 1, wherein the meter is connected to a common source of the wafer.

4. The testing apparatus for performing an avalanche test of claim 1, further comprising a blocking device connected to the second end of the inductor.

5. The testing apparatus for performing an avalanche test of claim 4, wherein the blocking device includes a diode.

6. The testing apparatus for performing an avalanche test of claim 1, wherein the meter is a current meter.

7. A testing method for performing an avalanche test, comprising the steps of:
sinking a current from a wafer chuck retaining a wafer having a plurality of transistors;
charging an inductor with a first end connected to a drain terminal of the transistor;
synchronously turning on the transistor and stopping the charging of the inductor; and
measuring the current flowing through a source terminal of the transistor.

8. The testing method for performing an avalanche test of claim 7, wherein the charging of the inductor is performed by a power source through a switch.

9. The testing method for performing an avalanche test of claim 8, wherein the turning on of the transistor and the turning off of the switch are performed synchronously.

10. The testing method for performing an avalanche test of claim 7, wherein the sinking a current from a wafer chuck includes grounding the wafer chuck.
